(19) United States
(12) Patent Application Publication
(10) Pub. No.: US 2010/0163890 A1
(43) Pub. Date: Jul. 1, 2010

(54) LED LIGHTING DEVICE

(76) Inventor: Michael Miskin, Sleepy Hollow, IL (US)

Correspondence Address: FACTOR & LAKE, LTD, 1327 W. WASHINGTON BLVD., SUITE 5G/H, CHICAGO, IL, 60607, US

(21) Appl. No.: 12/449,590

(22) PCT Filed: Oct. 25, 2007
(86) PCT No.: PCT/US2007/022686

§ 371 Date: Jan. 6, 2010

Related U.S. Application Data
(60) Provisional application No. 60/901,817, filed on Feb. 14, 2007.
(60) Provisional application No. 60/890,583, filed on Feb. 19, 2007.

(51) Int. Cl. H01L 33/62

(52) U.S. Cl. 257/88; 257/99; 257/E33.066

(57) ABSTRACT

An LED lighting device comprising an integral body comprising a dielectric thermally conductive polymer has an electrically conductive material directly attached to, or at least in part is molded within the body and forms a circuit pattern. Two or more LED die each having at least a portion thereof being attached directly either to one of a portion of the first body for direct thermal conduction or a portion of the electrically conductive material for direct electrical and thermal conduction or both. The integral body is optionally molded to have integral cooling surfaces such as fins. The integral body also may take a shape conforming to a mounting structure of a lighting fixture and may also include thereon additional electrical components for assisting the LED die in producing light, in other words drive components. Terminals may be integrally molded or formed in the body upon which a portion of the conductive material resides for electrical connection to another device such as a power source.

### CROSS REFERENCE TO RELATED APPLICATIONS

This application relies on the priority of U.S. Provisional Application No. 60/901,817 filed Feb. 14, 2007 and U.S. Provisional Application No. 60/890,583 filed Feb. 19, 2007, both of which are incorporated herein by reference.

### TECHNICAL FIELD

The invention relates to light emitting diode (“LED”) packaging and more particularly to LED assemblies to be installed in lighting fixtures.

### BACKGROUND OF THE INVENTION

### Description of the Related Art

Light-Emitting Diode (LED), device that emits visible light or infrared radiation when an electric current passes through it. LEDs are made of semiconductors, or electrical conductors, mixed with phosphors, substances that absorb electromagnetic radiation and reemit it as visible light. When electrical current passes through the diode the semiconductor emits infrared radiation, which the phosphors in the diode absorb and reemit as visible light. The visible emission is useful for indicator lamps and alphanumeric displays in various electronic devices and appliances. Devices such as remote controls and cameras that focus automatically use infrared LEDs, which emit infrared radiation instead of visible light. It is understood in the art that LEDs generally comprise an active region of semiconductor material sandwiched between two oppositely doped layers. When a bias is applied across the doped layers, holes and electrons are injected into the active region where they recombine to generate light. Light is emitted omnidirectionally from the active layer and from all non-covered surfaces of the LED. The substrate member may also include traces or metal leads for connecting the package to external circuitry and the substrate may also act as a heat sink to conduct heat away from the LED during operation.

It is known to provide semiconductor light emitting devices, such as a light emitting diode in a package that may provide a cover for protection of the die, color selection, focusing and the like for light emitted by the light emitting device. An LED package generally includes a substrate member on which a light emitting device or die is mounted. The light emitting device may, for example, include an LED chip/submount assembly mounted to the substrate member with electrical connections being made to the LED for applying an electrical bias.

As used herein, the terms “package,” “LED package,” or “lighting device” shall mean, for the most part, structures to which one or more LED die are mounted or into which the semiconductor die are integrated with attendant circuitry, for useful application of the light emitted from the die. A package may be a single die mounted to a substrate or may be multiple die mounted to one or more substrates, for example on a circuit board, or package. However, an LED device is any structure incorporating and LED die.

The LED has been increasingly applied to different applications in many different fields since it was invented. Today, it plays a very important role in lighting for many products and applications. In the past, light emitting diodes (LEDs) have been mostly used in indicator signal lights versus room or space lighting due to lack of brightness. However, with the advancements in LED technology and chip manufacturing technology, the usage of LEDs has become more diversified and they are being introduced into broader lighting markets including general and specialty lighting.

It is believed that about 22 percent of the electricity used in buildings in the United States is used for lighting, and of that, 40 percent is consumed by energy-inefficient incandescent lamps. LED lights are believed to be far more energy efficient than incandescent lights.

To be more successful in the new markets, LED devices are required to provide more light. Two ways in which this goal is being approached is increasing the number of LED's per lighting device and/or to increase the current through the LED die. Both of these approaches present significant challenges to thermal management of LED devices. First, as the brightness of an LED increases with increased current, so does the heat generated by the LED. Second, multiple LEDs in a device (e.g. in a luminaire) provides aggregated heat from the LED's. This is especially problematic when the lighting device is best designed to have a more or less localized origin of light, rather than more multiple dispersed origins of light. However, providing multiple LEDs in close proximity provides localized and aggregated heat build up.

These thermal management issues currently limit the scope of lighting fixture designs and applications using LED's. Hence, the thermal management of higher luminosity LED packages or devices becomes very important, especially the heat dissipation capability of the LED package structures incorporating LED die chips with a size greater than 24 mil.

Manufacturing and assembly of high power LED devices and products requires multiple steps. The LED die is first packaged then integrated onto a circuit board. The LED die is typically adhered into a package with epoxy, polymer, solder or other means. Placing LED die directly onto a circuit board is referred to as chip on board (COB). The LED package is then adhered to a circuit board with epoxy, polymer, solder or other means. The circuit board is typically made of fiberglass resin based material (FR4), ceramic or aluminum based on the power and thermal management requirements of the LED die or packaged LED being used. The circuit board is then mechanically mounted to a heat sink for added thermal dissipation capacity. The heat sink may include fins to increase the surface area of the heat sink thereby improving the thermal dissipation capacity of the mechanically combined structure. The circuit board is then integrated into a fixture or lumimaire which may further add thermal dissipation capacity based on the material, structure and thermal conductivity of the fixture or luminaire. In some cases the fixture or luminaire may have sufficient heat sinking capability with integrated fins eliminating the need to attach the LED circuit board to a finned heat sink prior to mounting it into the fixture.

Reducing one or more steps in the process of packaging LED die, assembling packaged LEDs onto a circuit board and/or integrating LED circuit boards into a fixture or luminaire could reduce the manufacturing and assembly cost of LED lighting products which in turn can be leveraged to the consumer.

In addition, every point of connection (surface to surface) between the die surface and a final surface of heat sinking bodies has the potential for introducing thermal transfer inefficiency. For example, even if a die is first directly attached to a first substrate which has significant thermal conductivity subsequent steps (or additions in the stack up) to create the final LED package—especially to the point of an assembly ready for a luminaire creates surface-to-surface interface resistance to thermal conductivity. In addition, some of the layers in the stack up, for example when a single LED die package is attached to a conventional circuit board—introduce a thermal insulator which reduces thermal conductivity efficiency or dissipation capacity.

The present invention addresses the deficiencies in the art while providing additional benefits as will be appreciated when considering the disclosures herein.

### SUMMARY OF THE INVENTION

According to an embodiment of the invention, an LED lighting device comprises a first integral body comprising a dielectric thermally conductive polymer having an electrically conductive material directly attached to, or formed within, the first body. The electrically conductive material forms a circuit pattern.

According to an embodiment of the invention at least one LED die is attached directly to an integral first body and a portion of the conductive material being electrically connected to the at least one LED die and the body having cooling surfaces being integrally formed thereon.

According to an embodiment of the invention at least one LED die is attached directly to the first body of thermally conductive polymer and at least a portion of the electrically conductive material being electrically connected to the at least one LED die and at least a portion of the electrically conductive material being embedded in the first body.

According to an embodiment of the invention, two or more LED die each have at least a portion thereof being attached directly to either one of a portion of the first body for direct thermal conduction or a portion of the electrically conductive material for direct electrical conduction, or both.

According to an embodiment of the invention, the first body is formed to have integral cooling surfaces, such as in the shape of cooling fins.

According to an embodiment of the invention, the first body may have formed integrally therein portions for aiding attachment of the first body to a lighting fixture, such as mounting lands, through holes, clips, blades, bulk heads, bezels, male or female snap fit structures, and the like.

According to an embodiment of the invention, the shape of the first body may be conveniently molded or formed to directly conform to a mounting structure or housing of a lighting fixture.

According to an embodiment of the invention, the first body may be attached directly to a second body wherein the second body has a higher thermal conductivity than that of the first body (such as metal or ceramic), the second body providing primarily heat dissipation from the first body to the second body.

According to an embodiment of the invention, the second body is advantageously formed from a thermally conductive polymer.

According to an embodiment of the invention, other electrical components for assisting the LED die in producing light (for example drive components) are also mounted to the first body and are electrically connected to the circuit pattern.

According to an embodiment of the invention, the body includes an integral portion thereof shaped to form a terminal with exposed conductive material thereon for connection with another body or fixture.

According to an embodiment of the invention, the first body may have formed integrally thereon angled surfaces proximate the locations of the die upon which to locate reflective materials or other structures integrally formed into the body such as lands, and through holes for wiring.

According to an embodiment of the invention, the first body having portions formed integrally into a surface thereof providing a land for the die.

According to an embodiment of the invention, the electrically conductive material is a thermoelectric material formed within the thermally conductive plastic and optionally the LED die is electrically bonded to the thermoelectric material.

According to an embodiment of the invention, the first body has at least one metal anode and at least one metal cathode lead frame insert molded within the thermally conductive polymer and electrically connected to the electrically conductive material.

According to an embodiment of the invention, a thermoelectric material layer is placed between the LED die and the first body.

According to an embodiment of the invention, the first body having at least one layer of thermoelectric material formed or molded within the thermally conductive polymer and the electrically conductive material being in formed on same.

### BRIEF DESCRIPTION OF THE DRAWINGS

FIG. 1 is a schematic top view of an embodiment of the invention;

FIG. 2 is a schematic side view of an embodiment of the invention;

FIG. 3 is a schematic top view of an embodiment of the invention;

FIG. 4 is a schematic top view of an embodiment of the invention;

FIG. 5 is a schematic side view of an embodiment of the invention;

FIG. 6 is a schematic top view of an embodiment of the invention;

FIG. 7 is a schematic top view of an embodiment of the invention;

FIG. 8 is a schematic side view of an embodiment of the invention;

FIG. 9 is a schematic side view of an embodiment of the invention; and,

### DETAILED DESCRIPTION OF THE INVENTION

The inventor of the present invention determined that it would be advantageous to improve the thermal dissipation capacity and/or efficiency of LED packages including that it would be advantageous to attach LED die as directly as possible to a heat sinking body while at the same time providing a simplification of the packaging of LEDs from die to luminaire. It was determined to provide fewer steps and contact points between the stack up from die to heat sink. For single die packages to luminaire it was determined that a single body of dielectric but thermally conductive material would present a workable platform. Thermally conductive polymers meet this criteria as well as being moldable in many ways, machinable and sufficiently durable. According to the invention, integrating multiple LED die directly into a thermally conductive package structure with integrated electrically conductive points that may be silk screened, printed or applied to the surface and/or embedded within the LED package in many cases eliminating thermally inefficient conventional circuit boards when building a luminaire. The invention provides for drive components to be integrated directly on or within a molded LED lighting device or package structure, such as a luminaire.

Representative examples of the thermally conductive polymer include Coolpoly® available from Cool Polymer Inc of the United States and LUCON 9000™ available from LG Chem, Ltd. of Korea. Some thermal conductive polymer based plastics exist such as Polyphenylene Sulfide “PPS” that allow for silk screening of circuitry onto their surfaces when made into an integral platform for forming a luminaire or a single die package. Other electrically conductive material may additionally be adhered to or insert molded into the thermally conductive plastics providing a combination of metals and plastics that both have similar thermally conductive properties. The polymers or plastics may be molded in any form including having small fins, mounting holes, etc.

Coolpoly® has a thermal conductivity in the range from 10 W/mK to 100 W/mK, which is a very high thermal conductivity in view of aluminum having a thermal conductivity of about 200 W/mK and common plastics have a thermal conductivity of about 0.2 W/mK. Coolpoly® also has relatively good workability such as formability.

LUCON 9000™ has a thermal conductivity in the range from 1 W/mK to 50 W/mK which is relatively lower than that of Coolpoly® but still shows a performance about 50 times or more with respect to common plastics. It is also known that LUCON 9000™ has better formability than Coolpoly®.

Considering desired thermal conductivity and formability, it is preferable that the thermally conductive polymer has a thermal conductivity of 10 or more.

The electrical insulation property of the material is measured as electrical resistivity and is typically in the range 10¹² to 10¹⁶ ohm-cm for both conventional plastics and D-Series plastics. The thermal conductivity of CoolPoly D-Series plastics enhances their electrical isolation and dielectric properties beyond the range of conventional plastics.

Conventional plastics are considered thermal insulators. The thermal conductivity of CoolPoly D-series thermally conductive plastics ranges from 1.0 W/mK to 10 W/mK. This exceptional level of thermal conductivity in a plastic is 5 to 100 times the value of conventional plastics. The optimal level of thermal conductivity for any application depends on the power input, size of the part and the convection conditions.

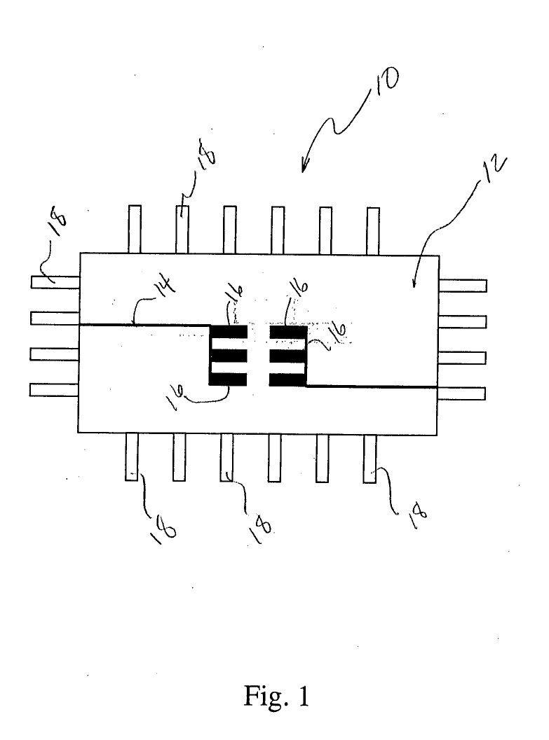

Turning now to the figures, FIG. 1 discloses an LED lighting device 10 comprising a first integral body 12 comprising a dielectric thermally conductive polymer. As used herein with respect to the thermally conductive polymer, “integral” means formed as a more or less homogeneous material into the body such as in a single molded piece. It is to be distinguished from bodies where two or more parts (even of the same material) are attached to each other. An electrically conductive material 14 such as copper or gold is directly attached to the first body 12 and forms a circuit pattern. The electrically conductive material 14 is connected to terminals 16 (or lead frames) where an LED die will be attached. As used herein, “attached directly” means a surface of one thing is touching a surface of the other thing to which it is attached directly without intervening substrates excepting for any means of fixing the two items together such as adhesives, solder, or being embedded into a molded body for example.

The electrically conductive material 14 connects the lead frames 16 to terminals (not shown in FIG. 1) for connection to a power source or other electrical unit. Six LED die (not shown in FIG. 1) each have at least a portion thereof being attached directly to one of either a portion of the first body 12 for direct thermal conduction or a portion of the lead frame 16 or both for electrical conduction. FIG. 1 discloses that the body has integrally formed to have cooling surfaces, in this case fins 18. Cooling surfaces as used herein should be understood to mean surfaces that but for their increasing the surface area of the body for cooling, have no other purpose. This is not to say that other surfaces such as attaching or mounting surfaces do not provide intended and beneficial cooling.

It should also be understood that like parts in differing embodiments disclosed herein shall use like reference numbers despite other differences between the embodiments, for example fins 18.

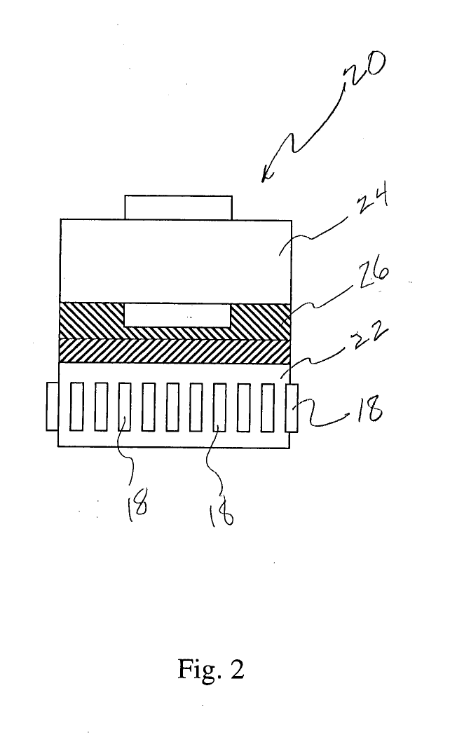

FIG. 2 discloses an LED lighting device 20 in the form of a package structure having an integral body 22 of thermally conductive polymer according to the invention with fins 18 integrally formed thereon. An LED die 24 is bonded to electrically conductive circuit material 14 formed by an adhesive or solder 24. In an alternate embodiment contemplated, a thermoelectric material may be formed within the body 22 beneath the LED die 24 to aid in drawing heat away for the LED die 24 and transferring it to the body 22 and fins 18 thereby improving dissipation capacity.

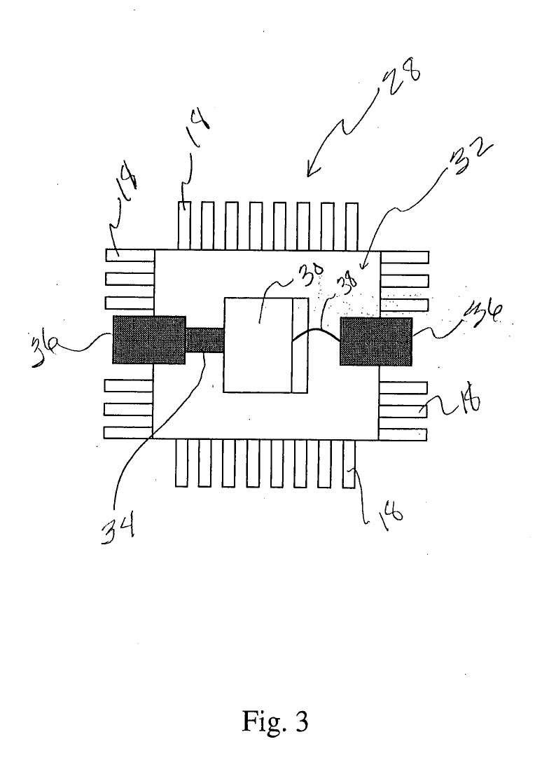

FIG. 3 discloses another LED lighting device 28 according to the invention where an LED die 30 is bonded to a thermally conductive plastic body 32. Fins 18 are formed within as part of the body 32 to provide increased surface area. In this embodiment the body 32 includes an integral portion thereof shaped to form terminals (lead frames) 36 for connection with another device or body. A portion of the conductive material 34 resides for electrical connection on the terminals 36 to achieve electrical connection of the LED die to another device such as a power source. Optionally the electrically conductive circuit material 34 is either formed on the terminals such as by silk screening, printing or other method or are in part molded within (embedded) the integral terminals 36 exposing only a necessary amount for electrical contact. A bond wire 38 is electrically bonded to the anode or cathode (as the case may be) of the LED die 30 and the anode or cathode is attached directly to a land on the lead frame 36.

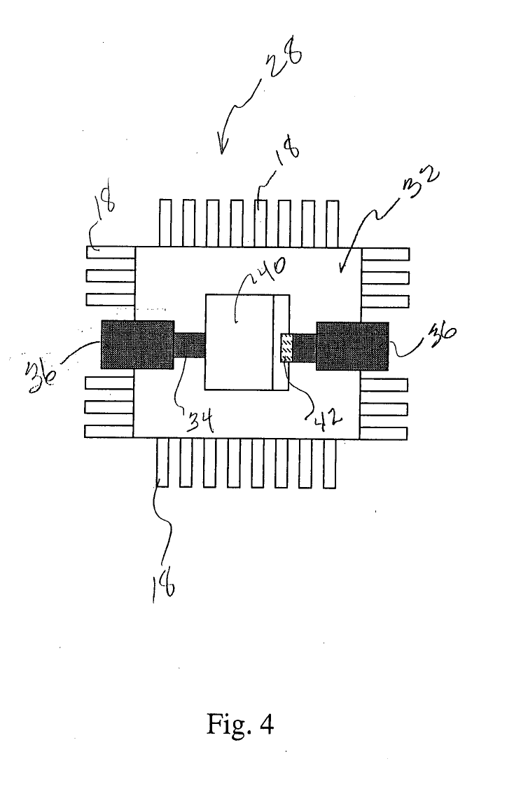

FIG. 4 discloses a different LED die 40 and connection schema for LED lighting device 28. The die 40 is electrically bonded by solder 42 to electrically conductive circuit material 34 formed within the body 32.

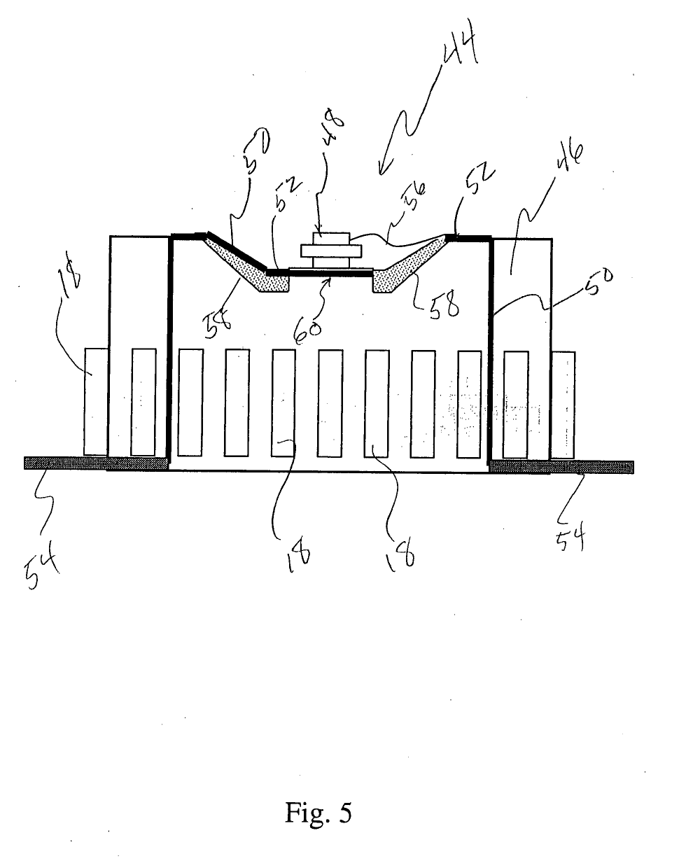

FIG. 5 discloses an LED lighting device with an integrally formed thermally conductive polymer body 46. A LED die 48 is bonded by solder or conductive high temperature adhesive to electrically conductive material 50 formed within the body 46. The electrically conductive circuit material 50 is also in large part formed within the body 46 and connects between the anode/cathode lead frames 52 to terminals (lead frames). The anode and cathode portion of the lead frames 552 have the electrically conductive circuit material 50 formed within or on the surface of the lead frames 56 by silk screening, printing and/or insert molding electrically conductive materials. A bond wire 56 is electrically bonded to the other of the anode/cathode lead frame 52.

FIG. 5 also discloses that the body 46 having formed integrally thereon angled surfaces 58 proximate the locations of the die 48 upon which to locate reflective materials. Also integrally formed into the shape of the body 46 is a flat “land” onto which the lead frames 50 or die 48 are mounted.

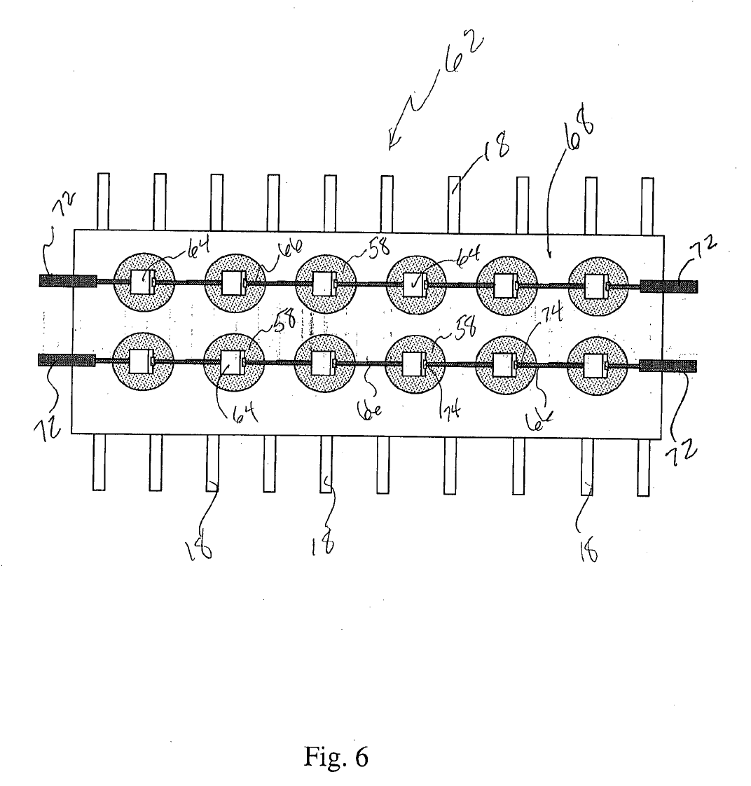

FIG. 6 discloses an LED package (or lighting device) 62 according to the invention wherein multiple LED die 64 are bonded to electrically conductive circuit material 66 formed within (embedded) a thermally conductive polymer body 68 by a high temperature adhesive or solder. The electrically conductive material may be insert-molded or formed within the body 68 to provide lead frames 72 and 74 that are electrically connected to the electrically conductive circuit material 66 formed within the body 68. The lead frames 72 may be supported by integrally formed terminal supports of the body 68.

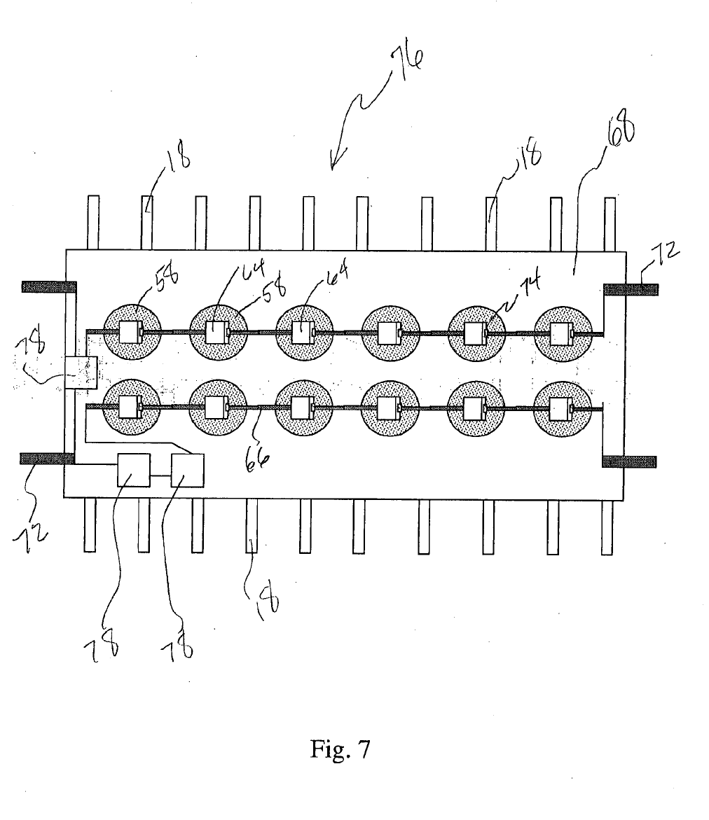

FIG. 7 discloses an LED lighting device 76 suitable for a luminaire (as may be other embodiments disclosed herein) having LED drive components 78 mounted or attached directly to the body 68.

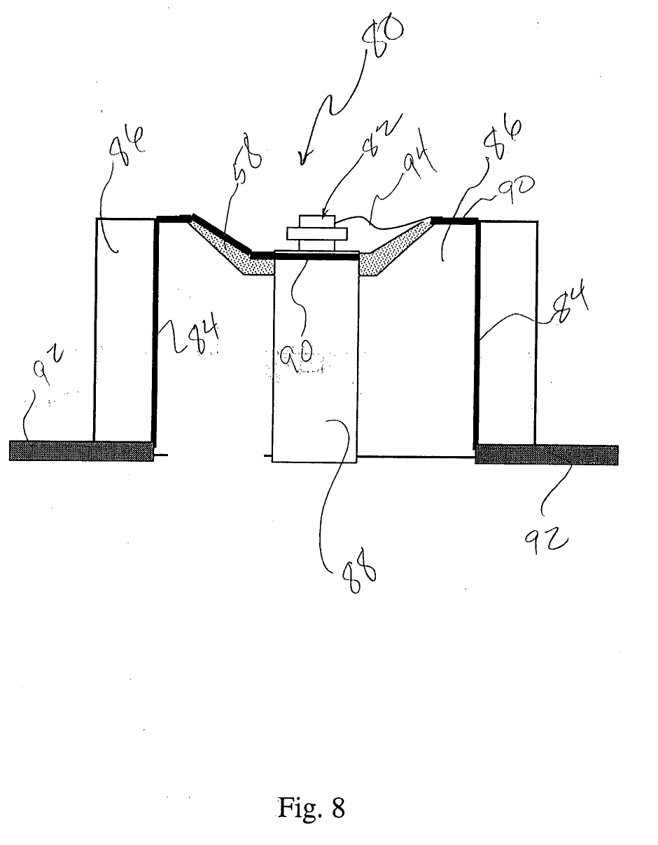

FIG. 8 discloses an LED lighting device 80 according to the invention where an LED die 82 is bonded by solder or conductive high temperature adhesive to electrically conductive material 84 formed within a thermally conductive polymer body 86. A second body 88 comprised metal or ceramic is located within the body 86 and may be embedded therein during a molding of the body 86. Electrically conductive circuit material 84 connects anode/cathode lead frames 90 to terminals 90 may also be thermally conductive plastic with a conductive material 84 thereon by silk screening, printing laser annealing, laser polymerization or embedded within (by over molding, insert molding or the like) the terminals 92. A bond wire 94 is electrically bonded to an anode/cathode of the LED die 82.

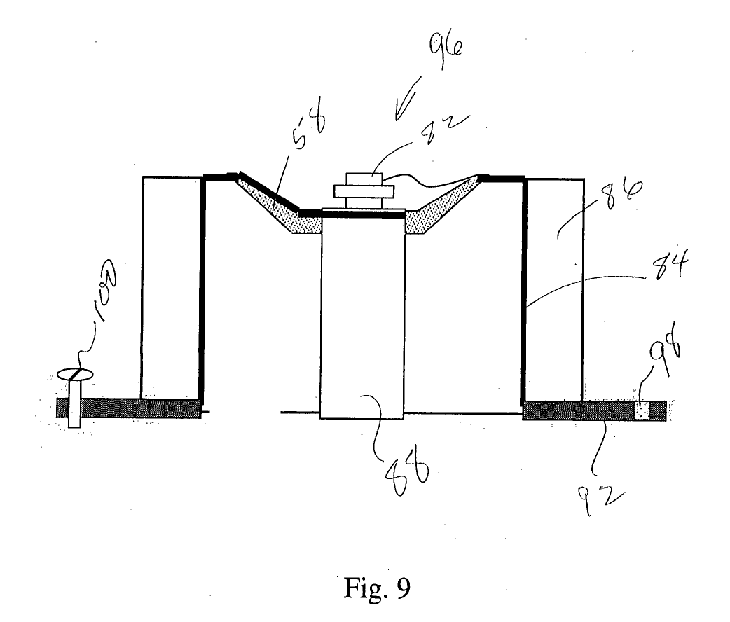

FIG. 9 discloses an LED lighting device, package or luminaire 96 which is similar in all respects to device 80 but for illustration purposes it is noted that the shape of the first body 86 conforms to a mounting structure of a lighting fixture. In addition the body 86 has mounting through holes 98 for electrical and/or mechanical coupling to another body or a light fixture. These through holes are integrally formed with the body 98.

The descriptions and summary of the invention herein are to be taken as exemplary teachings of the invention and are not to be read as limitations of the invention which is identified in the attached claims. Many other embodiments of the invention will also be within the scope of the invention as can be ascertained by those of skill in the art in view of these teachings.

1. An LED lighting device comprising:
a first integral body comprising a dielectric thermally conductive polymer;
an electrically conductive material directly attached to the first body and forming a circuit pattern and at least a portion thereof providing an electrical connection to the die; and,
two or more LEDs each having at least a portion thereof being attached directly to one of either a portion of the first body for direct thermal conduction or a portion of the electrically conductive material for direct electrical conduction.

2. The LED lighting device of claim 1 wherein the first body is formed to have cooling surfaces (define).

3. The LED lighting device of claim 2 wherein the cooling surfaces comprise fins.

4. The LED lighting device of claim 1 wherein the first body having formed integrally therein portions for aiding attachment of the first body to a lighting fixture.

5. The LED lighting device of claim 1 wherein the shape of the first body conforming to a mounting structure of a lighting fixture.

6. The LED lighting device of claim 1 wherein the first body is attached directly to a second body wherein the second body has a higher thermal conductivity than that of the first body, and the second body providing primarily heat dissipation from the first body to the second body.

7. The LED lighting device of claim 5 wherein the second body is formed from a thermally conductive polymer.

8. The LED lighting device of claim 1 wherein electrical components for assisting the LED die in producing light are also mounted to the first body and are electrically connected to the circuit.

9. The LED lighting device of claim 1 wherein at least a portion of the conductive material is embedded within the first body.

10. The LED lighting device of claim wherein the body includes an integral portion thereof shaped to form a terminal for connection with another body and upon which a portion of the conductive material resides for electrical connection to another device such as a power source.

11. The LED lighting device of claim 8 wherein the electrical components comprise a complete drive circuit for the LEDs.

12. The LED lighting device of claim 1 wherein the first body having formed integrally thereon angled surfaces proximate the locations of the die upon which to locate reflective materials.

13. The LED lighting device of claim 1 wherein the first body having portions formed integrally into a surface thereof providing a land for the die.

14. An LED lighting device comprising:
at least one LED die attached directly to an integral first body of thermally conductive polymer;
electrically conductive material forming a circuit pattern, a portion of which being electrically connected to the at least one LED die; and,
the body having cooling surfaces being integrally formed thereon.

15. An LED lighting device comprising:
at least one LED die attached directly to an integral first body of thermally conductive polymer; and,
electrically conductive material forming a circuit pattern, a portion of which being electrically connected to the at least one LED die and at least a portion of the electrically conductive material being embedded in the first body.

16. The LED lighting device of claim 14 wherein the cooling surfaces are in the form of fins.

17. The LED lighting device of claim 14 wherein at least a portion of the electrically conductive material is embedded within the first body.

18. The LED lighting device of claims 14 wherein the first body includes an integral portion thereof shaped to form a terminal for connection with another body and upon which a portion of the electrically conductive material provides for electrical connection to another device.

19. The LED lighting device of claim 14 and 15 wherein the first body is attached directly to a second body wherein the second body has a higher thermal conductivity than that of the first body, and the second body providing primarily heat dissipation from the first body to the second body.

20. The LED lighting device of claim 14 wherein the second body is formed from any one of a thermally conductive polymer, a metal or a ceramic.

21. The LED lighting device of claim 1 wherein the electrically conductive material is a thermoelectric material formed within the thermally conductive plastic.

22. The LED lighting device of claim 20 wherein the LED die is electrically bonded to the thermoelectric material.

23. The LED lighting device of claim 1 wherein the first body has at least one metal anode and at least one metal cathode lead frame insert molded within the thermally conductive polymer and electrically connected to the electrically conductive material.

24. The LED lighting device of claim 20 wherein a thermoelectric material layer is placed between the LED die and the first body.

25. The LED lighting device of claim 1 wherein the first body having at least one layer of thermoelectric material formed or molded within the thermally conductive plastic and the electrically conductive material being in formed on same.
